(19) United States
(12) Patent Application Publication
(10) Pub. No.: US 2025/0087578 A1
(43) Pub. Date: Mar. 13, 2025

(54) SEMICONDUCTOR DEVICE AND METHOD OF MANUFACTURING THEREOF

(71) Applicant: Taiwan Semiconductor Manufacturing Company, Ltd., Hsinchu (TW)

(72) Inventors: Chun-Yuan Chen, Hsinchu (TW); Sheng-Tsung Wang, Hsinchu (TW); Huan-Chieh Su, Changhua County (TW); Chih-Hao Wang, Hsinchu County (TW); Meng-Huan Jao, Taichung City (TW)

(73) Assignee: Taiwan Semiconductor Manufacturing Company, Ltd., Hsinchu (TW)

(21) Appl. No.: 18/463,297

(22) Filed: Sep. 8, 2023

(51) Int. Cl. H01L 23/522; H01L 21/768; H01L 29/417

(52) U.S. Cl. CPC H01L 23/5226; H01L 21/76805; H01L 21/76814; H01L 21/76816; H01L 21/76883; H10D 30/6729; H01L 21/02063; H10D 84/83

(57) ABSTRACT

A semiconductor device and a method of manufacturing thereof are provided. The method comprises: forming a gate electrode over a substrate; forming source/drain regions beside the gate electrode; forming contact plugs on the source/drain regions; forming a dielectric layer over the contact plugs and the gate electrode; forming first openings and a second opening in the dielectric layer to expose portions of the contact plugs and a portion of the gate electrode respectively; performing a pre-clean process such as applying an ozone-containing source to the exposed portions of the contact plugs and the gate electrode; performing a surface treatment to the first and second openings to passivate sidewalls of the first and second openings; forming a conductive layer to fill the first openings and the second opening in a same deposition process by using a same metal precursor; and performing a planarization process.

### BACKGROUND

With the continuing shrinking of the sizes of integrated circuits, lower contact resistance is playing an increasingly more important role in the improvement of the performance of the integrated circuits. Reducing resistance of contact vias is one of the factors in the performance improvement.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 illustrate the cross-sectional views of intermediate structures at various stages of the method for forming contact plugs in accordance with some embodiments of the present disclosure.

FIGS. 7-14 illustrate the cross-sectional views of intermediate structures at various stages of the method for forming contact vias in accordance with some embodiments of the present disclosure.

FIGS. 15A-15C illustrate schematic cross-sectional views of contact vias in accordance with some embodiments of the present disclosure.

FIGS. 16-18 illustrate the cross-sectional views of intermediate structures at various stages of the method for forming back-side contact vias in accordance with some embodiments of the present disclosure.

FIG. 19 illustrates the process flow of the method for forming contact plugs and contact vias in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure describes semiconductor devices, such as field-effect transistors (FETs), such as planar FETs, fin-type FETs (FinFETs), nano-sheet transistors, or gate all around (GAA) transistors.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure. Source/drain region(s) may refer to a source or a drain, individually or collectively dependent upon the context.

A semiconductor device, and a method of manufacturing thereof are provided. In accordance with some embodiments of the present disclosure, liner-free contact vias are formed in openings. The liner-free contact vias are each in direct contact with a conductive layer such as a source/drain contact plug, a gate electrode or any suitable metallic layer. The formation of the contact vias by performing a pre-clean process on a surface of the conductive layer within the openings, performing a surface treatment on sidewalls of a dielectric layer exposed by the openings, depositing a conductive layer by using a metal precursor to fill the openings, and partially removing the conductive layer to form the contact vias. Performing the pre-clean process may be applying an ozone-containing source on the openings to remove a residue comprising oxide. Therefore, the liner-free contact vias may be fabricated at the same stage to simplify a process design and reduce a fabrication cost such as reducing a number of lithography masks and reducing a number of metallization processes. Meanwhile, the liner-free contact vias may have a reduced resistance and improved conductivity. Compared with via contacts having liner(s), the Rc (contact resistance) of the liner-free contact vias is reduced by 10%-60%, and the gain of RO (ring oscillator) performance of the liner-free contact vias is increased by 1%-6%. Also, the transition rates between on and off states of the transistors with liner-free contact(s) are improved. By reducing the contact resistance, the conductivity is increased, and the performance and the efficiency of the transistors are improved.

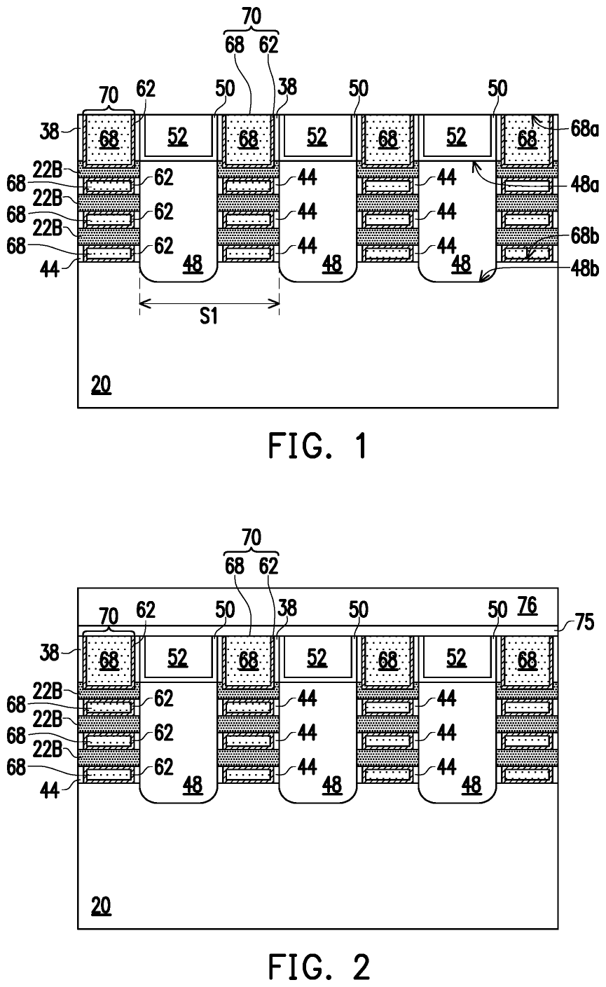

FIGS. 1-6 illustrate the cross-sectional views of intermediate structures at various stages of the method for forming contact plugs in accordance with some embodiments of the present disclosure.

Referring to FIG. 1, a substrate 20 is provided. In some embodiments, the substrate 20 may be a portion of a wafer having a multilayer structure or comprising multilayer stacks. In accordance with some embodiments, the substrate 20 is a semiconductor substrate 20, which may be a silicon substrate, a silicon germanium (SiGe) substrate, or the like, while other substrates and/or structures, such as semiconductor-on-insulator (SOI), strained SOI, silicon germanium on insulator, or the like, could be used. The substrate 20 may be doped as a p-type semiconductor, although in other embodiments, it may be doped as an n-type semiconductor.

Gate spacers 38 are formed on sidewalls of dummy gate stacks (not shown) on the multilayer stacks. In accordance with some embodiments of the present disclosure, the gate spacers 38 are formed of a dielectric material such as silicon nitride (SiN), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are the gate spacers 38.

In accordance with some embodiments, the multilayer stacks are formed through a series of deposition processes for depositing alternating materials. In accordance with some embodiments, multilayer stack comprises a plurality of sacrificial layers (not shown) and a plurality of semiconductor layers 22B alternately on the substrate 20. The semiconductor layers 22B are formed of or comprise a semiconductor material such as Si, SiGe, Ge, GaAs, InSb, GaSb, InAlAs, InGaAs, GaSbP, GaAsSb, or any suitable material for channels of GAA transistors.

In accordance with some embodiments, the deposition of the sacrificial layers (not shown) and the semiconductor layers 22B (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the semiconductor layers 22B may be formed to a thickness in the range between about 10 Å and about 500 Å. However, any suitable thickness may be utilized while remaining within the scope of the embodiments. The deposition process is repeated until a desired number of the semiconductor layers 22B has been formed. In accordance with some embodiments, a number of the semiconductor layers 22B may be 2 or more, or 2 to 6.

Inner spacers 44 are formed between adjacent semiconductor layers 22B, after the sacrificial layers (not shown) are laterally recessed to form lateral recesses. The inner spacers 44 act as isolation features between subsequently formed source/drain regions and a gate structure. The formation process may include depositing a conformal dielectric layer and then trimming the conformal dielectric layer. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 44.

Although the inner sidewalls and the out sidewalls of the inner spacers 44 are schematically illustrated as being straight in FIG. 1, the inner sidewalls of the inner spacers 44 may be convex, and the outer sidewalls of the inner spacers 44 may be concave or convex. The inner spacers 44 may be used to prevent the damage to subsequently formed source/drain regions, which damage may be caused by subsequent etching processes for forming replacement gate structures.

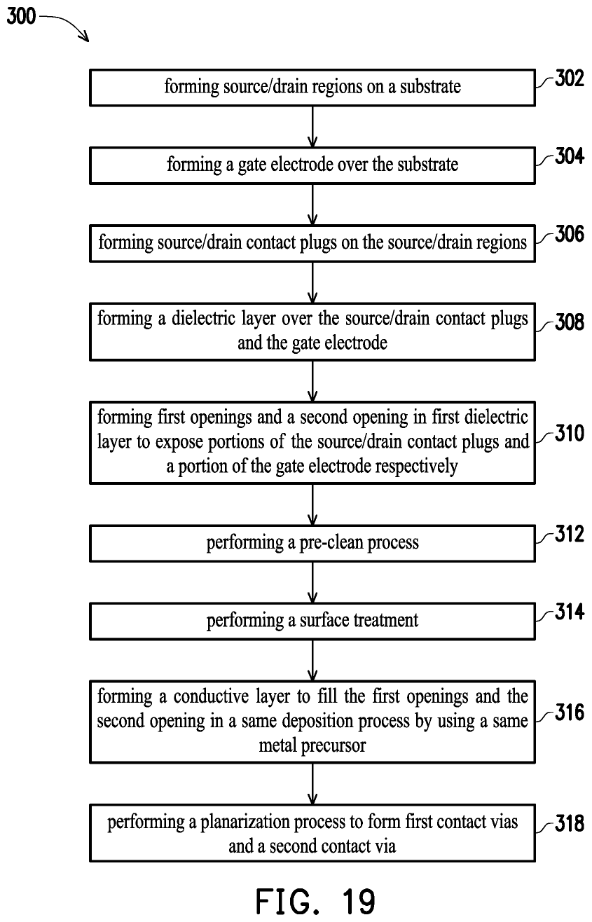

Epitaxial source/drain regions 48 are formed in recesses between the multilayer stacks on the substrate 20. The respective process is illustrated as process 302 in the process flow 300 as shown in FIG. 19. Epitaxial source/drain regions 48 has a first surface 48a and a second surface 48b opposite to the first surface 48a. In accordance with some embodiments, the source/drain regions 48 may exert stress on the semiconductor layers (nanostructures) 22B, which are used as the channels of the corresponding GAA transistors, thereby improving performance. Depending on whether the resulting transistor is a p-type transistor or an n-type transistor, a p-type or an n-type impurity may be in-situ doped with the proceeding of the epitaxy. For example, when the resulting transistor is a p-type Transistor, silicon germanium boron (SiGeB), silicon boron (SiB), or the like may be grown. Conversely, when the resulting transistor is an n-type Transistor, silicon phosphorous (SiP), silicon carbon phosphorous (SiCP), or the like may be grown. After the recesses are filled with epitaxy regions 48, the further epitaxial growth of epitaxy regions 48 causes epitaxy regions 48 to expand horizontally, and facets may be formed.

After the epitaxy process, epitaxy regions 48 may be further implanted with a p-type or an n-type impurity to form source and drain regions, which are also denoted using reference numeral 48. In accordance with alternative embodiments of the present disclosure, the implantation process is skipped when epitaxy regions 48 are in-situ doped with the p-type or n-type impurity during the epitaxy, and the epitaxy regions 48 are also source/drain regions.

A CESL 50 and an inter-layer dielectric (ILD) layer 52 are formed on the epitaxy regions 48 after a planarization process. The CESL 50 may be formed of silicon oxide, silicon nitride, silicon carbo-nitride, or the like, and may be formed using CVD, ALD, or the like. The ILD layer 52 may include a dielectric material formed using, for example, FCVD, spin-on coating, CVD, or any other suitable deposition method. The ILD layer 52 may be formed of an oxygen-containing dielectric material, which may be a silicon-oxide based material such as silicon oxide, Phospho-Silicate Glass (PSG), Boro-Silicate Glass (BSG), Boron-Doped Phospho-Silicate Glass (BPSG), Undoped Silicate Glass (USG), or the like.

Gate dielectrics 62 are formed in spaces between adjacent ones of semiconductor layers 22B and between the inner spacers 44, formed in spaces beneath the bottom ones of semiconductor layers 22B and in spaces between the gate spacers 38, after removing the dummy gate stack (not shown) and the sacrificial layers (not shown). In accordance with some embodiments, each of the gate dielectric 62 includes an interfacial layer and a high-k dielectric layer on the interfacial layer. The interfacial layer may be formed of or comprises silicon oxide, which may be deposited through a conformal deposition process such as ALD or CVD. In accordance with some embodiments, the high-k dielectric layers comprise one or more dielectric layers. For example, the high-k dielectric layer(s) may include a metal oxide or a silicate of hafnium, aluminum, zirconium, lanthanum, manganese, barium, titanium, lead, and combinations thereof.

Gate electrodes 68 are then formed. The respective process is illustrated as process 304 in the process flow 300 as shown in FIG. 19. Each gate electrodes 68 have a first surface 68a and a second surface 68b opposite to the first surface 68a. The second surface 68b of the gate electrodes 68 is closer to the substrate 20 than the first surface 68a of the gate electrodes 68. In the formation, the gate electrodes 68 are first formed on the high-k dielectric layer and filling the remaining portions of the spaces between adjacent ones of semiconductor layers 22B and between the inner spacers 44, the spaces beneath the bottom ones of semiconductor layers 22B and the spaces between the gate spacers 38. A material of gate electrodes 68 is different from a material of the source/drain contact plugs 94. The gate electrodes 68 may include a metal-containing material such as TiN, TaN, TiAl, TiAlC, cobalt, ruthenium, aluminum, tungsten, combinations thereof, and/or multilayers thereof. For example, although in FIG. 1, a single layer is illustrated to represent a gate electrode 68, the gate electrodes 68 may comprise any number of layers including any number of capping/adhesion layers, work function layers, and possibly a filling material. After the filling of the spaces between two source/drain regions 48, a planarization process such as a CMP process or a mechanical grinding process is performed to remove the excess portions of the gate dielectrics 62 and the material of the gate electrodes 68, which excess portions are over the top surface of ILD layer 52. The gate electrodes 68 and the gate dielectrics 62 are collectively referred to as gate stacks 70 of the resulting nano-FETs. In accordance with some embodiments, gate masks are formed on the gate electrodes 68. In accordance with some embodiments, a cross poly pitch S1 may range from about 35 nm to about 100 nm.

As further illustrated by FIG. 2, an etch stop layer 75 and an ILD layer 76 are deposited over the ILD layer 52 and the gate stacks 70. The etch stop layer 75 and the ILD layer 76 may be also called dielectric layers. In accordance with some embodiments, the etch stop layer 75 is formed through ALD, CVD, PECVD, or the like, and may be formed of silicon nitride, silicon carbide, silicon oxynitride, aluminum oxide, aluminum nitride, or the like, or multilayers thereof. The ILD layer 76 is formed through FCVD, CVD, PECVD, or the like. The ILD layer 76 is formed of a dielectric material, which may be selected from silicon oxide, PSG, BSG, BPSG, USG, or the like.

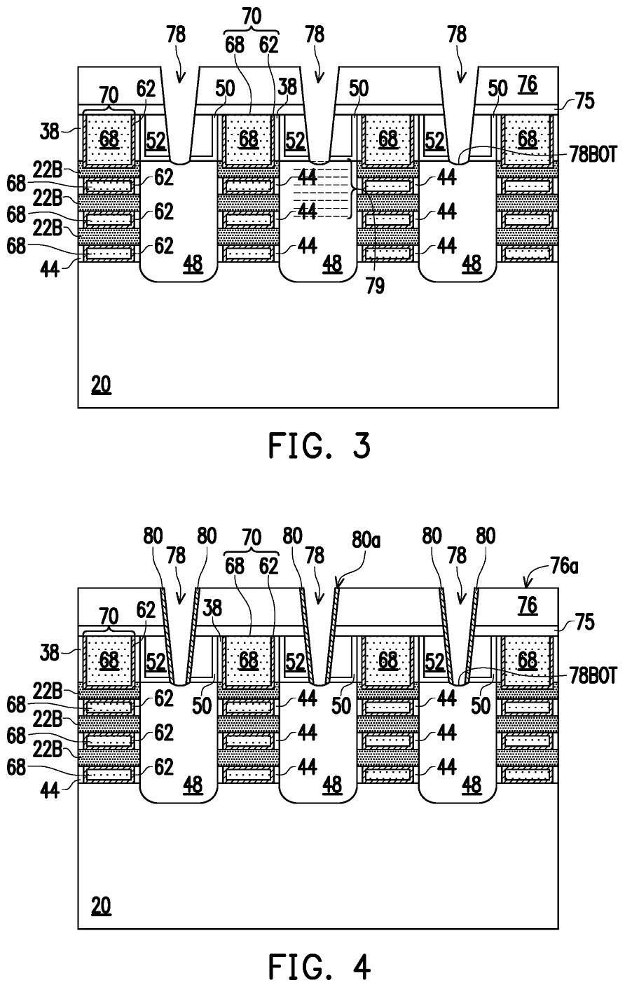

Referring to FIG. 3, the ILD layer 76, the etch stop layer 75, the ILD layer 52, and the CESL 50 are etched to form trenches 78 having bottoms 78BOT. In accordance with some embodiments, the ILD layer 76, the etch stop layer 75, and the ILD layer 52 may be etched using a same process gas or different processes. Next, the CESL 50 is etched to reveal the underlying source/drain regions 48. The etching process may be a dry etching process or a wet etching process, and the etching chemical depends on the material of the ILD layer 76, the etch stop layer 75, the ILD layer 52 and the CESL 50. After the CESL 50 is etched-through, an additional dry etching process is performed to etch source/drain regions 48, so that trenches 78 extend into the source/drain regions 48. The etching gas may include CxHyFz, HBr, Cl₂, and/or the like. Also, the etching gas may be different from the etching gas of the CESL 50 (if dry etching is adopted). The process conditions for etching source/drain regions 48 may be different from the process conditions for etching the CESL 50. For example, the bias power for the dry etching of source/drain regions 48 may be higher than the bias power for the dry etching of the CESL 50.

In accordance with some embodiments of the present disclosure, the bottoms 78BOT of trenches 78 are lower than a topmost layer of semiconductor layers 22B. The bottoms 78BOT of trenches 78 may also be at various levels relative to the levels of the topmost layer of semiconductor layers 22B. In accordance with some embodiments of the present disclosure, a plurality of dashed lines 79 are drawn to show possible positions of the bottoms 78BOT of trenches 78.

Referring to FIG. 4, isolation layers 80 (also called liner layers) are formed. The isolation layers 80 are formed of a dielectric material to prevent diffusion of metal plugs subsequent forming therein and improve the adhesion between the metal plugs and dielectric layers such as the ILD layer 76, the etch stop layer 75, the ILD layer 52, and the CESL 50. In accordance with some embodiments, the isolation layers 80 are formed of the dielectric material such as silicon nitride, silicon oxynitride, silicon oxide, silicon oxy-carbo-nitride, silicon carbon nitride, or the like. Next, an anisotropic etching process is performed to remove the horizontal portions of each isolation layers 80, leaving the vertical portions of each isolation layers 80, which forms a ring shape on the sidewall of the trenches 78 viewing from a top view. Top surfaces 80a of the isolation layers 80 are leveled with a top surface 76a of the ILD layer 76.

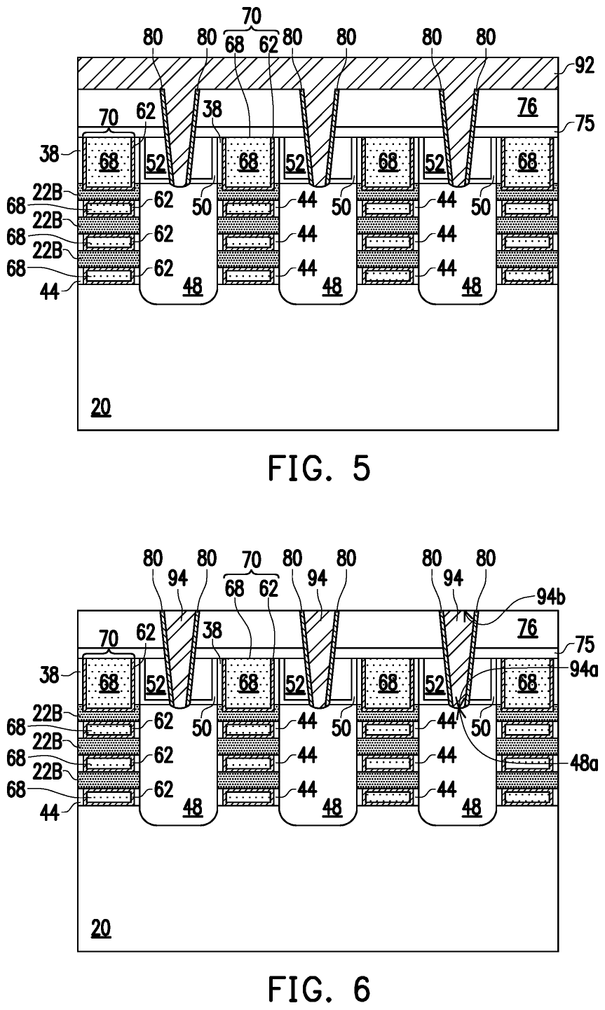

Referring to FIG. 5, a filling metal layer 92 such as W, Ru, Co, Cu, Mo, Ti, TaN, TiN, a combination thereof or the like, is deposited. In some embodiments, the filling metal layer 92 is formed by CVD, PVD, a plating process, or any suitable deposition process.

Referring to FIG. 6, the excess filling metal layer 92 is removed to form source/drain contact plugs 94 on the first surfaces 48a of the source/drain regions 48. The respective process is illustrated as process 306 in the process flow 300 as shown in FIG. 19. Sidewalls of the source/drain contact plugs 94 are surrounded and wrapped by the isolation layers 80 respectively. In accordance with some embodiments, a planarization process such as a CMP process or a mechanical grinding process may be performed to remove the excess filling metal layer 92, and then to form the source/drain contact plugs 94 with curved interfaces 94a between the source/drain contact plugs 94 and the exposed portions of the source/drain regions 48 respectively. The curved interfaces 94a are in direct contact with first surfaces 48a of the source/drain regions 48 respectively. Each of a center of the curved interface 94a protrudes toward the source/drain regions 48. In accordance with some embodiments, the critical dimensions (CD) of the source/drain contact plugs 94 range from 5 nm to 50 nm.

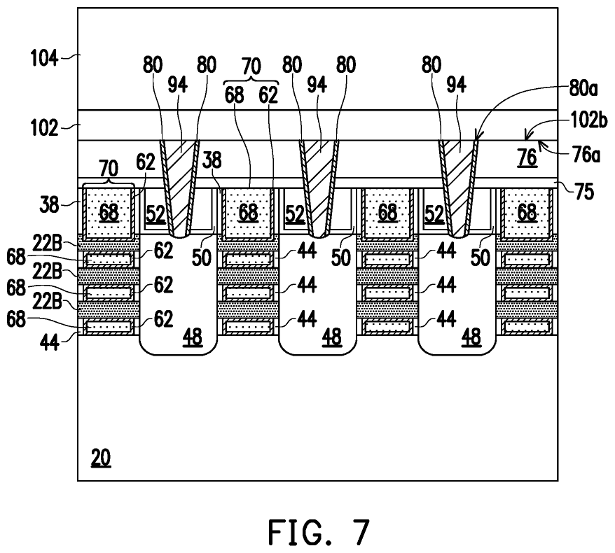

FIGS. 7-14 illustrate the cross-sectional views of intermediate structures at various stages of the method for forming contact vias in accordance with some embodiments of the present disclosure. The corresponding processes are also reflected schematically in the process flow shown in FIG. 19.

Referring to FIG. 7, an etch stop layer 102 and an ILD layer 104 are deposited over the source/drain contact plugs 94, the isolation layers 80 and the gate electrodes 68. The respective process is illustrated as process 308 in the process flow 300 as shown in FIG. 19. The etch stop layer 102 and the ILD layer 104 may be also called dielectric layers. In accordance with some embodiments, the etch stop layer 102 is formed through ALD, CVD, PECVD, or the like, and may be formed of silicon nitride, silicon carbide, silicon oxynitride, aluminum oxide, aluminum nitride, or the like, or multilayers thereof. ILD layer 104 is formed through FCVD, CVD, PECVD, or the like. The ILD layer 104 is formed of a dielectric material, which may be selected from silicon oxide, PSG, BSG, BPSG, USG, or the like. In accordance with some embodiments, a planarization process such as a CMP process or a mechanical grinding process is performed on the ILD layer 104. In accordance with some embodiments, the top surfaces 80a of the isolation layers 80 are substantially coplanar with the top surface 76a of the ILD layer 76 and a bottom surface 102b of the etch stop layer 102.

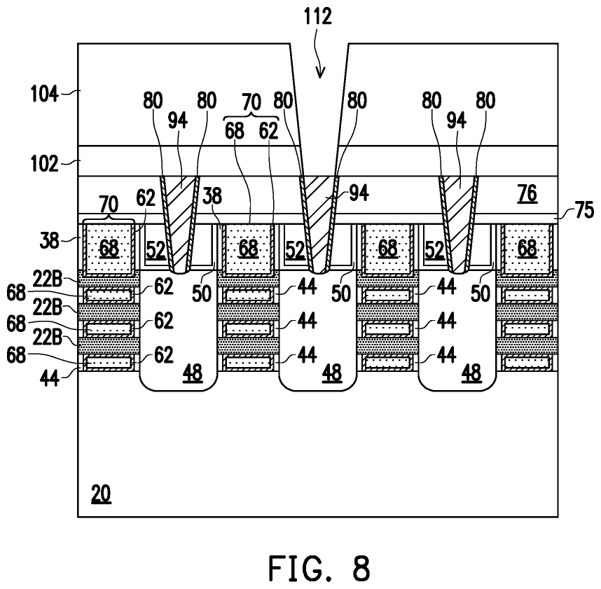

Referring to FIG. 8, in a first etching step, the ILD layer 104, the etch stop layer 102 are etched to reveal exposed portions of the source/drain contact plugs 94 and form openings 112. The respective process of FIGS. 8-10 are illustrated as process 310 in the process flow 300 as shown in FIG. 19. In accordance with some embodiments, the ILD layer 104 and the etch stop layer 102 may be etched using a same process gas or different processes. The etching process may be a dry etching process or a wet etching process, and the etching chemical depends on the material of the ILD layer 104 and the etch stop layer 102.

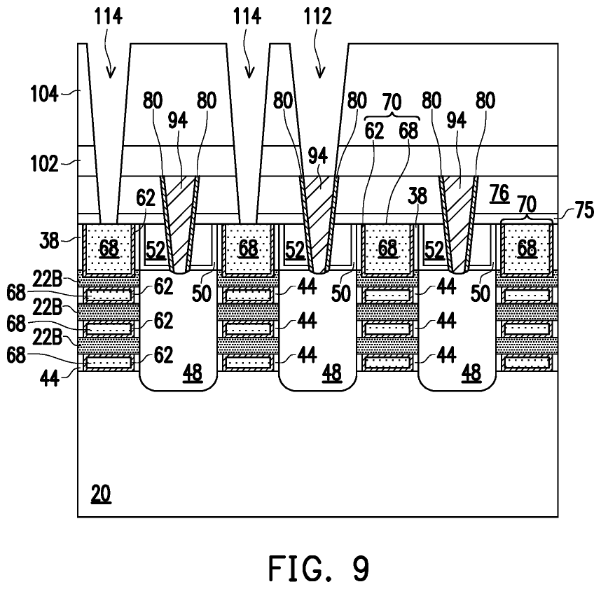

Referring to FIG. 9, in a second etching step, the ILD layer 104, the etch stop layer 102, the ILD layer 76 and the etch stop layer 75 are etched to reveal exposed portions of the gate electrodes 68 and form openings 114. In accordance with some embodiments, the ILD layer 104, the etch stop layer 102, the ILD layer 76 and the etch stop layer 75 may be etched using a same process gas or different processes. The etching process may be a dry etching process or a wet etching process, and the etching chemical depends on the material of the ILD layer 104, the etch stop layer 102, the ILD layer 76 and the etch stop layer 75.

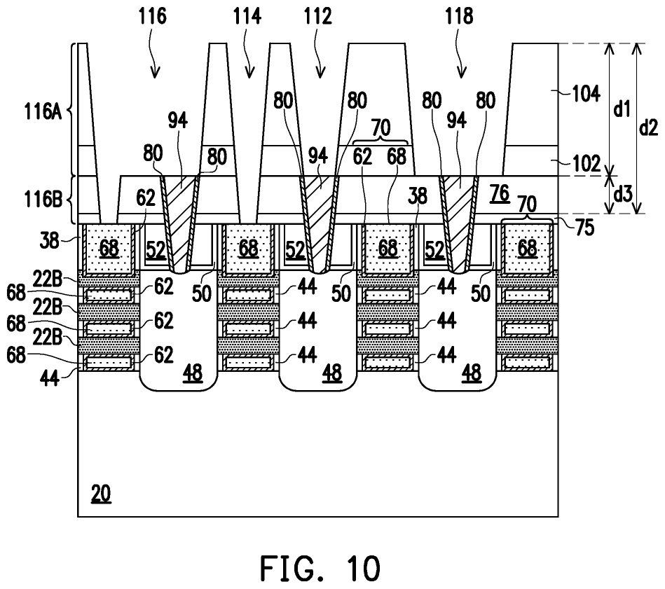

Referring to FIG. 10, in a third etching step, the ILD layer 104 and the etch stop layer 102 are etched to reveal exposed portions of the source/drain contact plugs 94 to form openings 116, 118. In accordance with some embodiments, and the ILD layer 104 and the etch stop layer 102 are etched to reveal exposed portions of the source/drain contact plugs 94 and connect with openings 112 exposing the gate electrodes 68 to form openings 116. The openings 116 comprise an upper portion 116A formed by the third etching step and a lower portion 116B formed by the first etching step. The upper portion 116A is within the ILD layer 104 and the etch stop layer 102. The lower portion 116B is within the etch stop layer 75 and the ILD layer 76. The lower portion 116B is a portion of the openings 114. In accordance with some embodiments, the critical dimensions (CD) of the upper portion 116A is greater than the critical dimensions (CD) of the lower portion 116B.

In accordance with some embodiments, and the ILD layer 104 and the etch stop layer 102 are etched to reveal exposed portions of the source/drain contact plugs 94 to form openings 118 within the ILD layer 104 and the etch stop layer 102. In accordance with some embodiments, the critical dimensions (CD) of the openings 118 is greater than the critical dimensions (CD) of the openings 112, 114. In accordance with some embodiments, the critical dimensions (CD) of the openings 112, 114, 116, 118 each range from about 5 nm to 50 nm.

In accordance with some embodiments, a depth d2 of the openings 114 is larger than a depth d1 of openings 112, 118 and the upper portion 116A of the openings 116, and larger than a depth d3 of the lower portion 116B of the openings 116. In accordance with some embodiments, the depth d1 of openings 112, 118 and the upper portion 116A of the openings 116 is larger than a depth d3 of the lower portion 116B of the openings 116. In accordance with some embodiments, the depths d1-d3 each range from about 5 nm to 40 nm. In accordance with some embodiments, the number and arrangement of the openings 112, 114, 116, 118 may be any suitable number and arrangement for a semiconductor device.

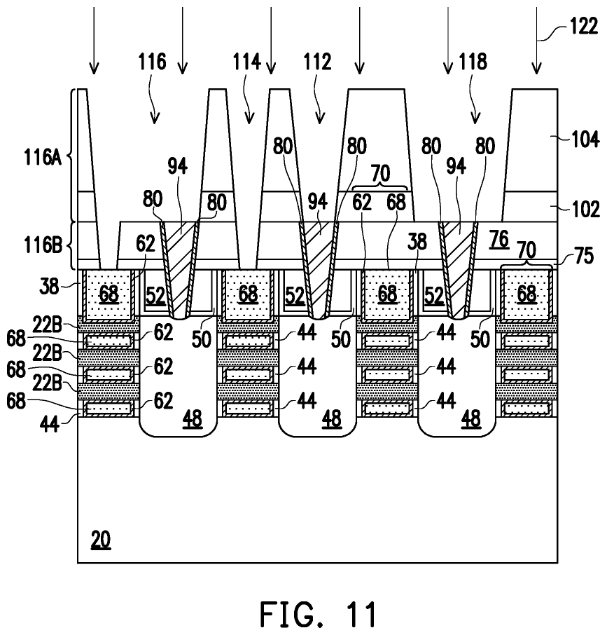

Referring to FIG. 11, a pre-clean process 122 is performed to the openings 112, 116, 118 and the exposed portions of the source/drain contact plugs 94, and is performed to opening 114, 116 and the exposed portions of the gate electrodes 68. The respective process is illustrated as process 312 in the process flow 300 as shown in FIG. 19. Then, residues comprising oxide on the surfaces of the source/drain contact plugs 94 and the gate electrodes 68 are removed by the pre-clean process 122. In accordance with some embodiments, residues comprising oxide are metal oxides. In accordance with some embodiments, performing the pre-clean process comprises applying an ozone-containing source, for example, soaking or spraying an ozone-containing source. The residues comprising oxide is derived from the previous planarization processes and etching processes. In accordance with some embodiments, the ozone-containing source is deionized ozone (DIO₃). The deionized ozone is ozone dissolved in DI water (deionized water). In accordance with some embodiments, performing the pre-clean process further comprises applying at least one of deionized water, HCl, ammonium hydroxide (NH₄OH), and isopropyl alcohol (IPA). In accordance with some embodiments, in the pre-clean process 122, the deionized ozone removes the oxide-based residues on the metal materials and removes the residues on the exposed portions of the source/drain contact plugs 94 and the gate electrodes 68, which is beneficial for achieving selective deposition of a metal or metallic material. That is, a metallic or metal material can be selectively deposited on the cleaned and treated metal surfaces of the metal materials in subsequent processes. In some embodiments, the metal or metallic material is selectively deposited on the metal surfaces in a bottom-up way (deposited from the bottom and growing upwards).

In accordance with some embodiments, the deionized ozone is applied to the openings 112, 114, 116, 118 for about 10 s to 500 s to remove the oxide-based residues from the exposed portions of the source/drain contact plugs 94 and the exposed portion of the gate electrodes 68. In accordance with some embodiments, the deionized ozone is applied to the openings 112, 114, 116, 118 at a concentration ranging from about 1 ppm to 1000 ppm, or 1 ppm to 100 ppm. In accordance with some embodiments, pre-clean process 122 is performed at a temperature ranging from about 50° C. to 400° C.

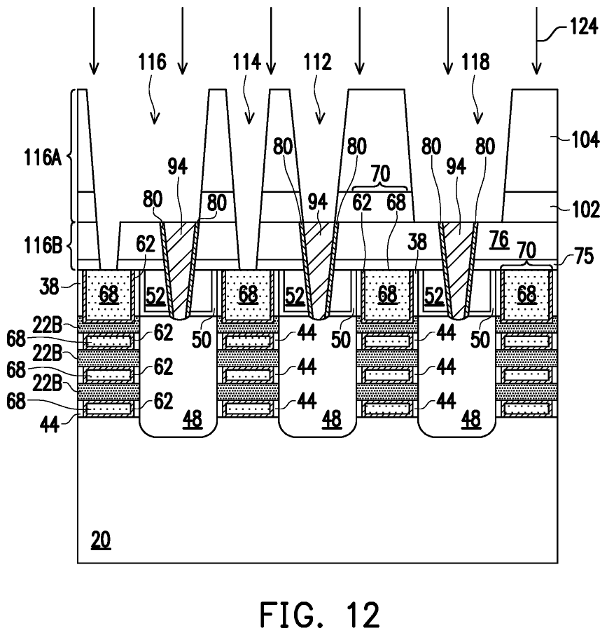

Referring to FIG. 12, a surface treatment 124 is performed to the openings 112, 114, 116, 118 to treat the exposed surfaces of the openings 112, 114, 116, 118. In some embodiments, the surface treatment 124 can passivate functional groups of sidewalls of dielectric layers (such as the ILD layers 76, 104, the etch stop layer 75, 102). The respective process is illustrated as process 314 in the process flow 300 as shown in FIG. 19. In accordance with some embodiments, the surface treatment 124 is performed to the exposed surfaces of the openings 112, 114, 116, 118, especially on the sidewalls of the dielectric layers (such as the ILD layers 76, 104, the etch stop layer 75, 102) exposed by the openings 112, 114, 116, 118. In accordance with some embodiments, performing the surface treatment includes a soaking process or a plasma treatment and a source gas used in the soaking process or the plasma treatment is N₂, H₂, O₂, Ar, NH₃, or a mixture thereof. In accordance with some embodiments, a power of the surface treatment is performed at OW (such as the soaking process), or performed in a range from greater than OW to about 10 kW (such as the plasma treatment). In accordance with some embodiments, the surface treatment is performed at a temperature ranging from about 50° C. to 450° C. In accordance with some embodiments, the surface treatment is performed at a pressure ranging from about 5 T to 1000 T. In accordance with some embodiments, in surface treatment 124, the functional groups of the sidewalls of the dielectric layers (such as the ILD layers 76, 104, the etch stop layer 75, 102) are passivated. Due to the passivation of the sidewalls of the dielectric layers, in subsequent processes, the metal or metallic material is more preferably deposited on the metal surfaces (such as the source/drain contact plugs 94 and the gate electrodes 68) in a bottom-up way (selectively deposited from the bottom and growing upwards in the openings 112, 114, 116, 118). Therefore, subsequent forming contact vias have improved adhesion with the metal surfaces and the dielectric layers.

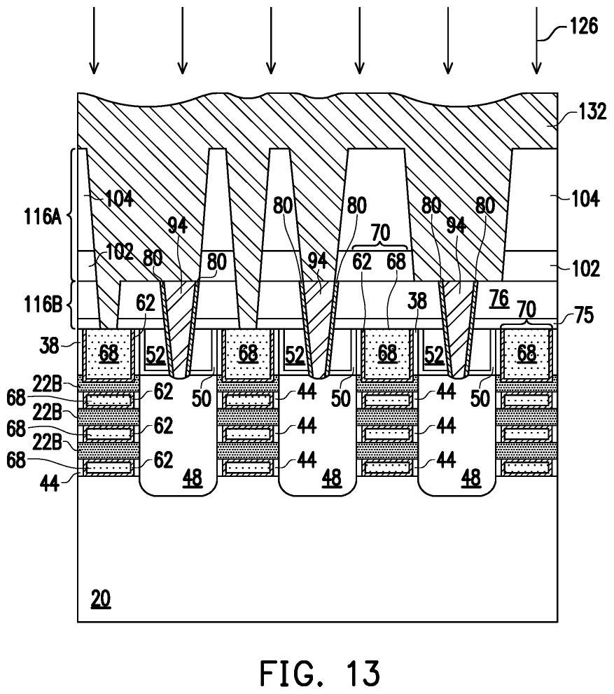

Referring to FIG. 13, a conductive layer 132 is formed to fill the openings 112, 114, 116, 118 in a same deposition process 126 by using a same metal precursor. In some embodiments, the conductive layer 132 is formed directly on the treated surfaces of the openings 112, 114, 116, 118 in a liner-free way. That is, the conductive layer 132 is in direct contact with the metal surfaces (such as the source/drain contact plugs 94 and the gate electrodes 68) as well as the passivated sidewalls of the dielectric layers (such as the ILD layers 76, 104, the etch stop layer 75, 102). The respective process is illustrated as process 316 in the process flow 300 as shown in FIG. 19. In accordance with some embodiments, the same deposition process 126 comprises a metal-organic chemical vapor deposition (MOCVD) process. In accordance with some embodiments, the same metal precursor comprises a metal complex compound containing a metal selected from W, Ru, Co, Cu, Mo, Ti, Ta, Ir, or a combination thereof; and a ligand selected from alkoxide, thiocyanate, nitrate, azide, acetonitrile, pyridine, ammonium, halide, or a combination thereof. In accordance with some embodiments, a material of the conductive layer 132 may be W, Ru, Co, Cu, Mo, Ti, TaN, TiN, a combination thereof or the like. In accordance with some embodiments, MOCVD process using the metal precursor with the specific ligand may selectively deposit metals on the metal surfaces in a bottom-up way. Thus, the metals preferably initially nucleate on the metal surfaces such as the source/drain contact plugs 94 and the gate electrodes 68 in similar deposition rate. Then, the openings 112, 114, 116, 118 with different depths may be complete filled by the metal. By a selective deposition to deposit from the bottom and growing upwards, the seamless contact vias are formed subsequently, and issues of adhesion and reliability of the contact vias may be also improved.

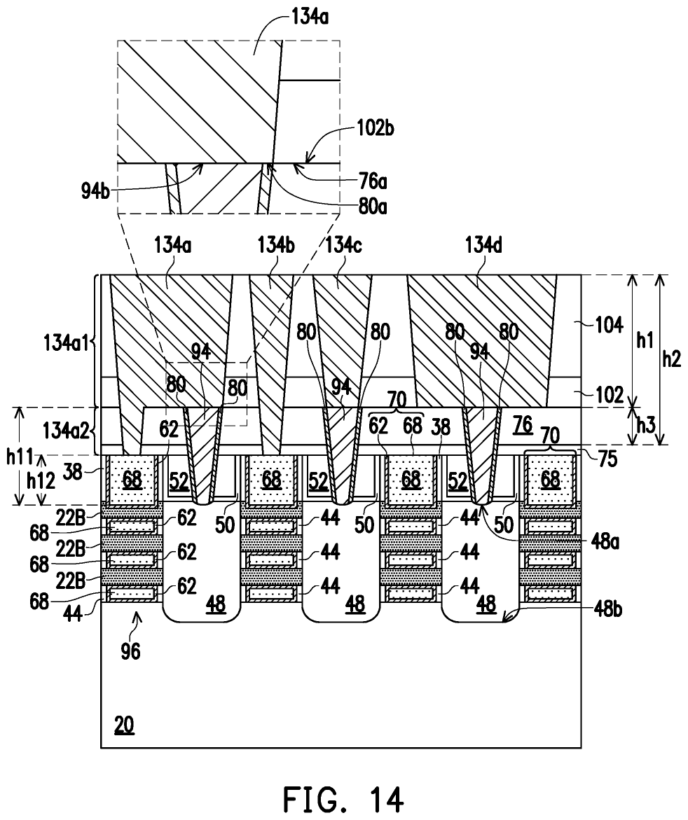

Referring to FIG. 14, a planarization process is performed to the conductive layer 132 to partially remove the conductive layer 132 to form liner-free contact vias 134a-134d at a same time. The respective process is illustrated as process 318 in the process flow 300 as shown in FIG. 19. In accordance with some embodiments, for the transistors 96, a height h11 of the source/drain contact plugs 94 is higher than a height h12 of the gate electrodes 68. In accordance with some embodiments, the height h11 of the source/drain contact plugs 94 are ranging about 5 nm to 40 nm. In accordance with some embodiments, the height h12 of the gate electrodes 68 are ranging about from 5 nm to 40 nm.

In some embodiments, the liner-free contact vias 134a-134d are formed as integral mass or block and made of the same metallic material. In accordance with some embodiments, the critical dimensions (CD) of the contact vias 134a-134d are individually ranging from about 5 nm to 50 nm. In accordance with some embodiments, heights of contact vias 134a-134d are individually ranging about 5 nm to 40 nm.

In accordance with some embodiments, heights h1-h3 is each corresponded to the depths d1-d3. In accordance with some embodiments, a height h2 of a contact via 134b within the openings 114 is larger than a height h1 of contact vias 134c, 134d within openings 112, 118 and an upper portion 134a1 of a contact via 134a within the upper portion 116A of the openings 116. In accordance with some embodiments, a height h2 of a contact via 134b within the openings 114 is larger than a height h3 of a lower portion 134a2 of a contact via 134a within the lower portion 116B of the openings 116. In accordance with some embodiments, the height h1 of contact vias 134c, 134d and the upper portion 134al of the contact via 134a is larger than a height h3 of the lower portion 134a2 of the contact via 134a.

In accordance with some embodiments, the source/drain contact plugs 94 are in direct contact with contact vias 134a, 134c, 134d through liner-free interfaces 94b. In accordance with some embodiments, the interface 94b of the source/drain contact plug 94 has a level substantially same as a level of the bottom surface 102b of the etch stop layer 102, the top surface 76a of the ILD layer 76 and the top surfaces 80a of the isolation layers 80. In one embodiment, an angle sandwiched between sidewalls of the contact vias 134a-134d and a bottom surface of the contact vias 134a-134d is about 80 degrees to about 90 degrees.

In accordance with some embodiments, without forming a liner layer there-between, a first contact via 134a penetrates through the ILD layer 104 and the etch stop layer 102 and is in direct contact with the exposed portions of the source/drain contact plugs 94 and the isolation layers 80, and penetrates through the ILD layer 104, the etch stop layer 102, the ILD layer 76 and the etch stop layer 75 and is in direct contact with the exposed portions of the first surface 68a of the gate electrodes 68. In accordance with some embodiments, the first contact via 134a is in direct contact with the exposed portions of the interfaces 94b of the source/drain contact plugs 94 and the top surfaces 80a of the isolation layers 80.

In accordance with some embodiments, a second contact via 134b penetrates through the ILD layer 104, the etch stop layer 102, the ILD layer 76 and the etch stop layer 75 and is in direct contact with the exposed portion of the first surface 68 of the gate electrodes 68. In accordance with some embodiments, a third contact via 134c and a fourth contact via 134d each penetrates through the ILD layer 104 and the etch stop layer 102 and are each in direct contact with the exposed portion of the source/drain contact plugs 94 and the isolation layers 80. In accordance with some embodiments, the third contact via 134c and a fourth contact via 134d is each in direct contact with the exposed portions of the interfaces 94b of the source/drain contact plugs 94 and the top surfaces 80a of the isolation layers 80.

In accordance with some embodiments, the sidewalls of the first contact via 134a and the second contact via 134b are each in direct contact with the ILD layer 104 and the etch stop layer 102, the ILD layer 76 and the etch stop layer 75. In accordance with some embodiments, sidewalls of the third contact via 134c and the fourth contact via 134d are each in direct contact with the ILD layer 104 and the etch stop layer 102.

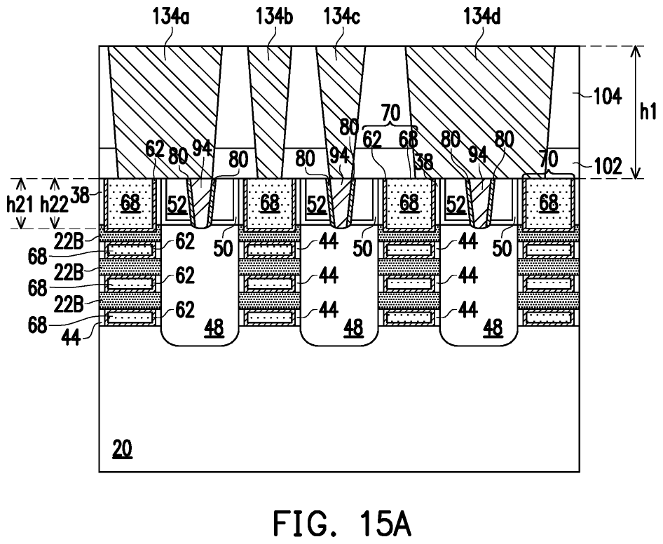

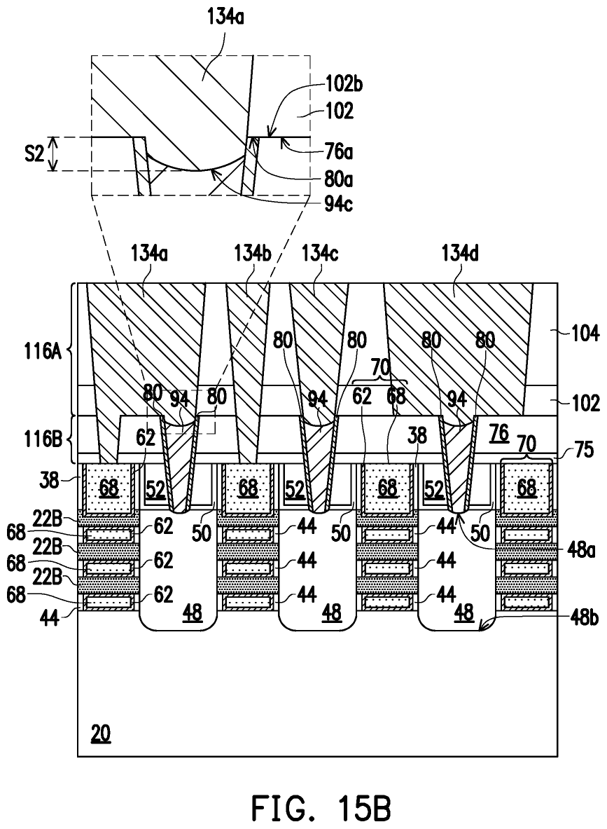

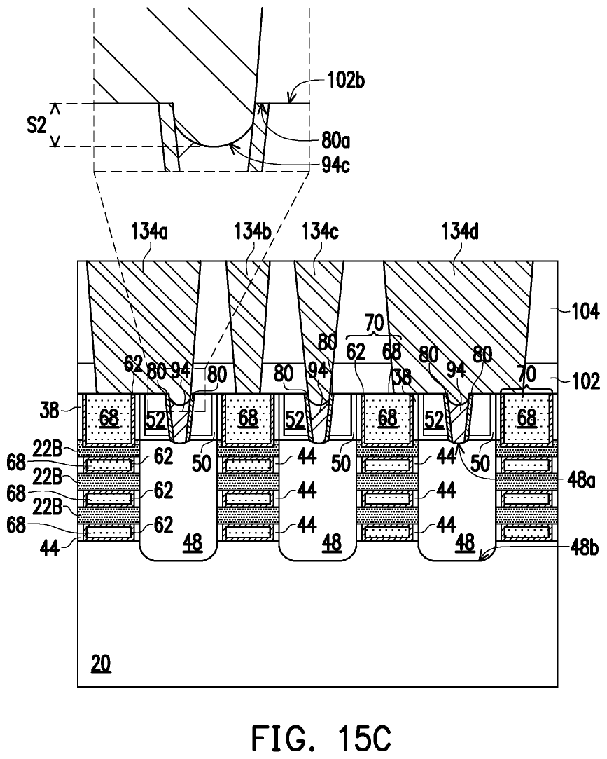

FIGS. 15A-15C illustrate schematic cross-sectional views of contact vias in accordance with some embodiments of the present disclosure.

FIG. 15A illustrate cross-sectional view of an intermediate stage in the formation of contact vias in accordance with some embodiments of the disclosure. The exemplary structures shown in FIG. 15A may be fabricated following the process steps as described in the previous embodiments as shown from FIG. 1 to FIG. 14, except the formation of the etch stop layer 75 and the ILD layer 76 and the formation of the source/drain contact plugs 94 and the isolation layers 80 within the etch stop layer 75 and the ILD layer 76. Similar materials may be used as described in the previous embodiments may be used. However, it is understood that any other compatible process steps or methods or any other suitable materials may be utilized and comprehensible modifications or adjustments may be made for forming the exemplary structure of this disclosure.

Referring to FIG. 15A, the conductive layer 132 is partially removed to form contact vias 134a-134d at the same time. The contact vias 134a-134d has a same height h1. In accordance with some embodiments, heights h1 of contact vias 134a-134d are each ranging about 5 nm to 40 nm.

In accordance with some embodiments, a height h21 of the source/drain contact plugs 94 is substantially the same as a height h22 of the gate electrodes 68. In accordance with some embodiments, a first contact via 134a and a fourth contact via 134d each penetrates through the ILD layer 104 and the etch stop layer 102 and is each in direct contact with the exposed portions of the source/drain contact plugs 94, the isolation layers 80 and the gate electrodes 68. In accordance with some embodiments, a second contact via 134b penetrates through the ILD layer 104 and the etch stop layer 102 and is in direct contact with the exposed portion of the gate electrodes 68. In accordance with some embodiments, a third contact via 134c penetrates through the ILD layer 104 and the etch stop layer 102 and is in direct contact with the exposed portion of the source/drain contact plugs 94 and the isolation layers 80.

In accordance with some embodiments, sidewalls of the first contact via 134a and the second contact via 134b, the third contact via 134c and the fourth contact via 134d are each in direct contact with the ILD layer 104 and the etch stop layer 102.

FIG. 15B illustrate cross-sectional view of an intermediate stage in the formation of contact vias in accordance with some embodiments of the disclosure. The exemplary structures shown in FIG. 15B may be fabricated following the process steps as described in the previous embodiments as shown from FIG. 1 to FIG. 14, except curved interfaces 94c exists between the source/drain contact plugs 94 and contact vias 134a, 134c, 134d. Similar materials may be used as described in the previous embodiments may be used. However, it is understood that any other compatible process steps or methods or any other suitable materials may be utilized and comprehensible modifications or adjustments may be made for forming the exemplary structure of this disclosure.

Referring to FIG. 15B, the contact vias 134a, 134c, 134d has a recess surface after etching processes for forming the openings 112, 114, 116, 118 and processes 122, 124, 126. In accordance with some embodiments, the contact vias 134a, 134c, 134d are formed with the curved interfaces 94c between the contact vias 134a, 134c, 134d and the exposed portions of the source/drain contact plugs 94 respectively. The curved interfaces 94c are in direct contact with the source/drain contact plugs 94 respectively. Each of a center of the curved interface 94c protrudes toward the first surfaces 48a of the source/drain regions 48 and has a level different from a level of the bottom surface 102b of the etch stop layer 102, the top surface 76a of the ILD layer 76 and the top surfaces 80a of the isolation layers 80. In accordance with some embodiments, a distance S2 between the center of each curved interfaces 94c and the bottom surface 102b of the etch stop layer 102, the top surface 76a of the ILD layer 76 and the top surfaces 80a of the isolation layers 80 is ranging from about 0.5 nm to 10 nm. In accordance with some embodiments, an area of each curved interfaces 94c may increase in a range from 10% to 1000% based on an area of each interface 94a shown in FIG. 14. As the contact area is increased, the contact resistance is reduced, which further improves the performance and the efficiency of the transistors.

FIG. 15C illustrate cross-sectional view of an intermediate stage in the formation of contact vias in accordance with some embodiments of the disclosure. The exemplary structures shown in FIG. 15C may be fabricated following the process steps as described in the previous embodiments as shown in FIG. 15A, except curved interfaces 94c exist between the source/drain contact plugs 94 and contact vias 134a, 134c, 134d. Similar materials may be used as described in the previous embodiments may be used. However, it is understood that any other compatible process steps or methods or any other suitable materials may be utilized and comprehensible modifications or adjustments may be made for forming the exemplary structure of this disclosure.

Referring to FIG. 15C, the contact vias 134a, 134c, 134d has a recess surface after etching processes and processes 122, 124, 126. In accordance with some embodiments, the contact vias 134a, 134c, 134d each has the curved interface 94c in direct contact with the source/drain contact plug 94. Each of a center of the curved interface 94c protrudes toward the first surface 48a of the source/drain regions 48 and has a level different from a level of the bottom surface 102b of the etch stop layer 102 and the top surfaces 80a of the isolation layers 80. In accordance with some embodiments, a distance S2 between the center of each curved interface 94c and the bottom surface 102b of the etch stop layer 102 and the top surfaces 80a of the isolation layers 80 is ranging from about 0.5 nm to 10 nm. In accordance with some embodiments, an area of each curved interface 94c may increase in a range from 10% to 1000% based on an area of each interface 94a shown in FIG. 14. The contact area is increased, the resistance may be reduced to improve the performance and the efficient of the resulting transistors.

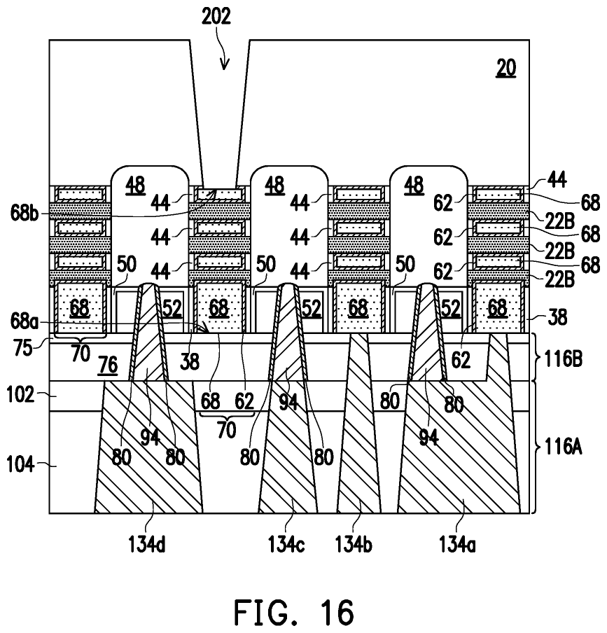

FIGS. 16-18 illustrate the cross-sectional views of intermediate structures at various stages of the method for forming back-side contact vias in accordance with some embodiments of the present disclosure.

Referring to FIG. 16, a structure is flipped upside down and etched the substrate 20 to reveal an exposed portion of the second surface 68b of the gate electrodes 68 and form an opening 202, after the formation of the contact vias 134a-134d shown in FIG. 14. In accordance with some embodiments, and the substrate 20 is thinned to a desired thickness by using a planarization process such as a CMP process, a grinding process, an etching process, the like, or a combination thereof. In accordance with some embodiments, the substrate 20 may be etched by etching processes. The etching process may be a dry etching process or a wet etching process, and the etching chemical depends on the material of substrate 20.

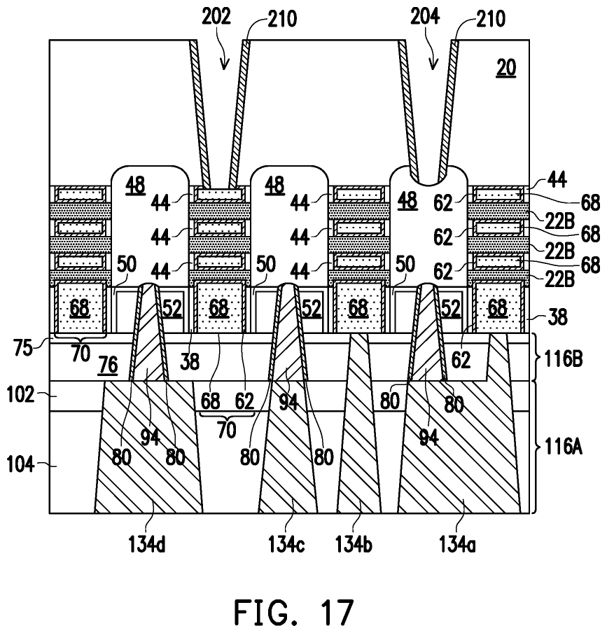

Referring to FIG. 17, the substrate 20 is etched to reveal an exposed portion of the second surfaces 48b of the source/drain regions 48 and form an opening 204. In accordance with some embodiments, the substrate 20 may be etched by etching processes. The etching process may be a dry etching process or a wet etching process, and the etching chemical depends on the material of substrate 20.

In accordance with some embodiments, isolation layers 210 are formed sidewalls of the openings 212, 214. In accordance with some embodiments, the isolation layers 210 are formed of a dielectric material such as silicon nitride, silicon oxynitride, silicon oxide, silicon oxy-carbo-nitride, silicon carbon nitride, or the like. Next, an anisotropic etching process is performed to remove the horizontal portions of each isolation layer 210, leaving the vertical portions of each isolation layer 210, which forms a ring shape on the sidewall of the openings 212, 214 viewing from a top view.

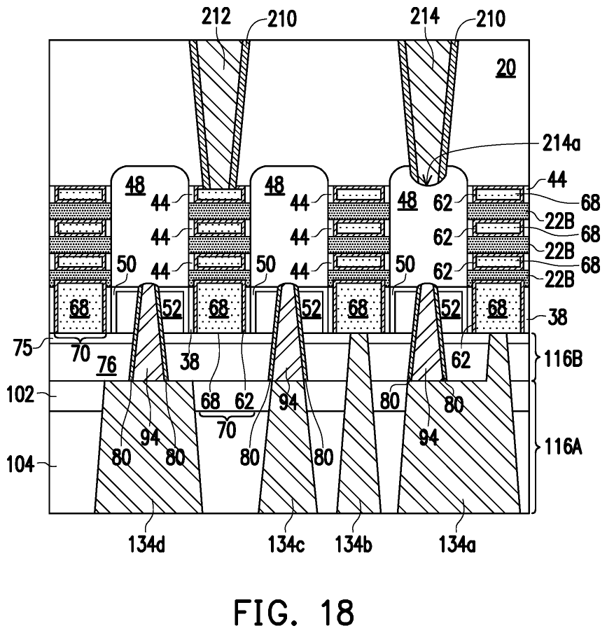

Referring to FIG. 18, contact vias 212, 214 are formed after a deposition process and the planarization process. A material of the contact vias 212, 214 is each such as W, Ru, Co, Cu, Mo, Ti, TaN, TiN, a combination thereof or the like. The planarization process such as a CMP process or a mechanical grinding process may be performed to remove an excess filling metal layer to form the contact vias 212, 214 each in direct contact with the second surface 68b of the gate electrodes 68 and the second surfaces 48b of the source/drain regions 48. The contact via 214 with a curved interface 214a in direct contact with first surfaces 48a of the source/drain regions 48. A center of the curved interface 214a protrudes toward the second surfaces 48b of the source/drain regions 48.

In accordance with some embodiments, the critical dimensions (CD) of the contact vias 212, 214 range from about 5 nm to 50 nm. In accordance with some embodiments, the heights of contact vias 212, 214 range from about 5 nm to 40 nm.

A semiconductor device, and a method of manufacturing thereof are provided. In accordance with some embodiments of the present disclosure, liner-free contact vias are formed in openings. The liner-free contact vias are each in direct contact with a conductive layer such as a source/drain contact plug, a gate electrode or any suitable metallic layer. The formation of the contact vias by performing a pre-clean process on a surface of the conductive layer within the openings, performing a surface treatment on sidewalls of a dielectric layer exposed by the openings, depositing a conductive layer by using a metal precursor to fill the openings, and partially removing the conductive layer to form the contact vias. Performing the pre-clean process may be applying an ozone-containing source on the openings to remove a residue comprising oxide. Therefore, the liner-free contact vias may be fabricated at the same stage to simplify a process design and reduce a fabrication cost such as reducing a number of lithography masks and reducing a number of metallization processes. Meanwhile, the liner-free contact vias may have a reduced resistance and improved conductivity. Compared with via contacts having liner(s), the Rc (contact resistance) of the liner-free contact vias is reduced by 10%-60%, and the gain of RO (ring oscillator) performance of the liner-free contact vias is increased by 1%-6%. Also, the transition rates between on and off states of the transistors with liner-free contact(s) are improved. By reducing the contact resistance, the conductivity is increased, and the performance and the efficiency of the transistors are improved.

In accordance with some embodiments of the present disclosure, a method for forming a semiconductor device comprises: forming a gate electrode over a substrate; forming source/drain regions beside the gate electrode and on the substrate; forming source/drain contact plugs on the source/drain regions; forming a first dielectric layer over the source/drain contact plugs and the gate electrode; forming first openings and a second opening in the first dielectric layer to expose portions of the source/drain contact plugs and a portion of the gate electrode respectively; performing a pre-clean process to the first openings and the exposed portions of the source/drain contact plugs, and to the second opening and the exposed portion of the gate electrode, wherein performing the pre-clean process comprises applying an ozone-containing source; performing a surface treatment to the first and second openings to passivate sidewalls of the first and second openings of the first dielectric layer; forming a conductive layer to fill the first openings and the second opening in a same deposition process by using a same metal precursor; and performing a planarization process to partially remove the conductive layer to form first contact vias in direct contact with the exposed portions of the source/drain contact plugs and to form a second contact via in direct contact with the exposed portion of the gate electrode.

In accordance with some embodiments of the present disclosure, a method comprises: forming a gate electrode over a substrate; forming source/drain regions beside the gate electrode and on the substrate; forming an inter-layer dielectric (ILD) layer on the source/drain regions; forming trenches penetrating through the ILD layer to expose portions of the source/drain regions; forming isolation layers on sidewalls of the trenches respectively; forming source/drain contact plugs on the source/drain regions, on the isolation layers and within the trenches, wherein sidewalls of the source/drain contact plugs are surrounded by the isolation layers respectively, and a material of the source/drain contact plugs is different from a material of the gate electrode; forming a first dielectric layer over the source/drain contact plugs, the isolation layers and the gate electrode; forming first openings and a second opening in the first dielectric layer to expose portions of the source/drain contact plugs and a portion of the gate electrode respectively; performing a pre-clean process to the first openings and the exposed portions of the source/drain contact plugs, and to the second opening and the exposed portion of the gate electrode, wherein performing the pre-clean process comprises applying an ozone-containing source; performing a surface treatment to the first and second openings to passivate sidewalls of the first and second openings of the first dielectric layer; forming a conductive layer to fill the first openings and the second opening in a same deposition process; and forming first contact vias in the first openings in direct contact with the exposed portions of the source/drain contact plugs and the isolation layers, and to form a second contact via in the second opening in direct contact with the exposed portion of the gate electrode.

In accordance with some embodiments of the present disclosure, a semiconductor device comprises a gate electrode, source/drain regions, source/drain contact plugs, isolation layer, a first dielectric layer, a first contact via, and a second contact via. The gate electrode is disposed on a semiconductor substrate. The source/drain regions are disposed on the semiconductor substrate and located at opposite sides of the gate electrode. The source/drain contact plugs are disposed on the source/drain regions. The isolation layers surrounds and wraps sidewalls of the source/drain contact plugs respectively. The first dielectric layer is disposed over the source/drain contact plugs, the isolation layers and the gate electrode. The first contact vias penetrate through the first dielectric layer and are in direct contact with the source/drain contact plugs and the isolation layers. The second contact via penetrates through the first dielectric layer and is in direct contact with the gate electrode. The first contact vias and the second contact via have different heights and are liner-free contact vias.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
forming a gate electrode over a substrate;
forming source/drain regions beside the gate electrode and on the substrate;
forming source/drain contact plugs on the source/drain regions;
forming a first dielectric layer over the source/drain contact plugs and the gate electrode;
forming first openings and a second opening in the first dielectric layer to expose portions of the source/drain contact plugs and a portion of the gate electrode respectively;
performing a pre-clean process to the first openings and the exposed portions of the source/drain contact plugs, and to the second opening and the exposed portion of the gate electrode, wherein performing the pre-clean process comprises applying an ozone-containing source;
performing a surface treatment to the first and second openings to passivate sidewalls of the first and second openings of the first dielectric layer;
forming a conductive layer to fill the first openings and the second opening in a same deposition process by using a same metal precursor; and
performing a planarization process to partially remove the conductive layer to form first contact vias in direct contact with the exposed portions of the source/drain contact plugs and to form a second contact via in direct contact with the exposed portion of the gate electrode.

2. The method of claim 1, wherein the ozone-containing source includes deionized ozone, and performing the pre-clean process further comprises applying at least one of deionized water, HCl, ammonium hydroxide (NH₄OH), and isopropyl alcohol (IPA).

3. The method of claim 2, wherein the deionized ozone is applied to the first and second openings for about 10 s to 500 s to remove residues from the exposed portions of the source/drain contact plugs and the exposed portion of the gate electrode.

4. The method of claim 2, wherein the deionized ozone is applied to the first and second openings at a concentration ranging from about 1 ppm to 1000 ppm.

5. The method of claim 1, wherein performing the surface treatment includes performing a soaking process or a plasma treatment using a source gas selected from N₂, H₂, O₂, Ar, NH₃, or a mixture thereof.

6. The method of claim 1, wherein the same deposition process comprises a metal-organic chemical vapor deposition (MOCVD) process.

7. The method of claim 6, wherein the same metal precursor comprises a metal complex compound containing a metal selected from W, Ru, Co, Cu, Mo, Ti, Ta, Ir, or a combination thereof, and a ligand selected from alkoxide, thiocyanate, nitrate, azide, acetonitrile, pyridine, ammonium, halide, or a combination thereof.

8. The method of claim 1, wherein forming the first openings and the second opening further comprises forming the first openings having a first depth and the second opening having a second depth that is larger than the first depth.

9. The method of claim 1, wherein the first contact vias are formed with curved interfaces between the first contact vias and the exposed portions of the source/drain contact plugs respectively.

10. A method, comprising:
forming a gate electrode over a substrate;
forming source/drain regions beside the gate electrode and on the substrate;
forming an inter-layer dielectric (ILD) layer on the source/drain regions;
forming trenches penetrating through the ILD layer to expose portions of the source/drain regions;
forming isolation layers on sidewalls of the trenches respectively;
forming source/drain contact plugs on the source/drain regions, on the isolation layers and within the trenches, wherein sidewalls of the source/drain contact plugs are surrounded by the isolation layers respectively, and a material of the source/drain contact plugs is different from a material of the gate electrode;
forming a first dielectric layer over the source/drain contact plugs, the isolation layers and the gate electrode;
forming first openings and a second opening in the first dielectric layer to expose portions of the source/drain contact plugs and a portion of the gate electrode respectively;
performing a pre-clean process to the first openings and the exposed portions of the source/drain contact plugs, and to the second opening and the exposed portion of the gate electrode, wherein performing the pre-clean process comprises applying an ozone-containing source;
performing a surface treatment to the first and second openings to passivate sidewalls of the first and second openings of the first dielectric layer;
forming a conductive layer to fill the first openings and the second opening in a same deposition process; and
forming first contact vias in the first openings in direct contact with the exposed portions of the source/drain contact plugs and the isolation layers, and to form a second contact via in the second opening in direct contact with the exposed portion of the gate electrode.

11. The method of claim 10, wherein the ozone-containing source includes deionized ozone, and performing the pre-clean process further comprises applying at least one of deionized water, HCl, ammonium hydroxide (NH₄OH), and isopropyl alcohol (IPA).

12. The method of claim 11, wherein the deionized ozone is applied in a concentration ranging from about 1 ppm to 1000 ppm to the first and second openings for about 10 s to 500 s.

13. The method of claim 10, wherein the first openings are formed with a first depth to expose the portions of the source/drain contact plugs and the second opening is formed with a second depth to expose the portion of the gate electrode, and the second depth is larger than the first depth.

14. The method of claim 10, wherein performing the surface treatment includes performing a soaking process or a plasma treatment, using a source gas selected from N₂, H₂, O₂, Ar, NH₃, or a mixture thereof.

15. The method of claim 10, wherein the same deposition process comprises a metal-organic chemical vapor deposition (MOCVD) process.

16. The method of claim 15, wherein the MOCVD process is performed using a metal complex compound containing a metal selected from W, Ru, Co, Cu, Mo, Ti, Ta, Ir, or a combination thereof, and a ligand selected from alkoxide, thiocyanate, nitrate, azide, acetonitrile, pyridine, ammonium, halide, or a combination thereof.

17. A semiconductor device, comprising:
a gate electrode disposed on a semiconductor substrate;
source/drain regions disposed on the semiconductor substrate and located at opposite sides of the gate electrode;
source/drain contact plugs disposed on the source/drain regions;
isolation layers, surrounding and wrapping sidewalls of the source/drain contact plugs respectively;
a first dielectric layer disposed over the source/drain contact plugs, the isolation layers and the gate electrode;
first contact vias penetrating through the first dielectric layer and in direct contact with the source/drain contact plugs and the isolation layers; and
a second contact via penetrating through the first dielectric layer and in direct contact with the gate electrode, wherein the first contact vias and the second contact via have different heights and are liner-free contact vias.

18. The semiconductor device of claim 17, wherein a material of the second contact via is the same as a material of the first contact vias.

19. The semiconductor device of claim 17, wherein a height of the second contact via is larger than a height of the first contact vias.

20. The semiconductor device of claim 17, wherein the first contact vias are in direct contact with the source/drain contact plugs with curved interfaces respectively.
